(19) United States
(12) Patent Application Publication
(10) Pub. No.: US 2026/0026149 A1
(43) Pub. Date: Jan. 22, 2026

(54) METHOD OF MANUFACTURING DISPLAY APPARATUS AND AN ELECTRONIC DEVICE INCLUDING THE SAME

(71) Applicant: Samsung Display Co., Ltd., Yongin-si (KR)

(72) Inventors: Jeongho Yi, Yongin-si (KR); Yeongjun Kim, Yongin-si (KR); Laeho Kim, Yongin-si (KR); Bongsik Noh, Yongin-si (KR); Jinwon Baek, Yongin-si (KR); Taeho Lee, Yongin-si (KR); Donghoon Hyun, Yongin-si (KR)

(21) Appl. No.: 19/265,881

(22) Filed: Jul. 10, 2025

(30) Foreign Application Priority Data
Jul. 18, 2024 (KR) 10-2024-0095278

(51) Int. Cl. H10H 29/03; H10H 29/01

(52) U.S. Cl. CPC H10H 29/03; H10H 29/012

(57) ABSTRACT

A method of manufacturing a display apparatus is provided. The method of manufacturing the display apparatus includes disposing, on a jig part, a display panel including a first electrode and a second electrode, spraying, on the display panel, a plurality of light emitters, each of the plurality of light emitters including a light-emitting element and a solution, primarily aligning the plurality of light emitters by applying a first-1 voltage to the first electrode and applying a first-2 voltage to the second electrode, and secondarily aligning the plurality of light emitters by applying a second-1 voltage to the first electrode and applying a second-2 voltage to the second electrode.

### CROSS-REFERENCE TO RELATED APPLICATION

The present application claims priority to and the benefit of Korean Patent Application No. 10-2024-0095278, filed on Jul. 18, 2024, in the Korean Intellectual Property Office, the entire disclosure of which is incorporated by reference herein.

### BACKGROUND

### 1. Field

One or more embodiments relate to a method, and more particularly, to a method of manufacturing a display apparatus and an electronic device including the same.

### 2. Description of the Related Art

Mobile electronic apparatuses are widely used. Tablet personal computers (PCs) as well as miniaturized electronic apparatuses such as mobile phones have been recently widely used as mobile electronic apparatuses.

To support various functions, for example, to provide a user with visual information such as images, the mobile electronic apparatuses include a display apparatus. Recently, as the parts configured to drive a display apparatus have been miniaturized, the proportion of display apparatuses in electronic apparatuses has gradually increased and a structure that may be bent to a preset angle with respect to a flat state has been developed.

### SUMMARY

One or more embodiments of the present disclosure provide a method of manufacturing a display apparatus, wherein light emitters (e.g., light emitting elements) are controlled by using an electric field such that the light emitters (e.g., light emitting elements) are uniformly distributed after being sprayed on a display panel.

However, such a technical feature or aspect is just an example, and the present disclosure is not limited thereto.

Additional aspects will be set forth in part in the description which follows and, in part, will be apparent from the description, or may be learned by practice of the presented embodiments of the present disclosure.

According to one or more embodiments, a method of manufacturing a display apparatus includes disposing, on a jig part, a display panel including a first electrode and a second electrode, spraying, on the display panel, a plurality of light emitters, each of the plurality of light emitters including a light-emitting element and a solution, primarily aligning the plurality of light emitters by applying a first-1 voltage to the first electrode and applying a first-2 voltage to the second electrode, and secondarily aligning the plurality of light emitters by applying a second-1 voltage to the first electrode and applying a second-2 voltage to the second electrode.

In one or more embodiments, compared to intervals between the light-emitting elements of the plurality of light emitters during the spraying of the plurality of light emitters, during the primarily aligning of the plurality of light emitters, intervals between the light-emitting elements of the plurality of light emitters may be more uniform on a plane.

In one or more embodiments, the first-1 voltage may be a direct current voltage.

In one or more embodiments, the first-1 voltage may be an alternating current voltage.

In one or more embodiments, a waveform of the first-1 voltage may change over time.

In one or more embodiments, the first-2 voltage may be a ground voltage.

In one or more embodiments, the light-emitting element may include a first semiconductor layer, a second semiconductor layer, and an active layer between the first semiconductor layer and the second semiconductor layer.

In one or more embodiments, during the secondarily aligning of the plurality of light emitters, the first semiconductor layer may be in contact with the second electrode, and the second semiconductor layer may be in contact with the first electrode.

In one or more embodiments, the second-1 voltage may be a direct current voltage.

In one or more embodiments, the second-2 voltage may be a ground voltage.

According to one or more embodiments, a method of manufacturing a display apparatus includes disposing, on a jig part, a display panel including a first electrode and a second electrode, spraying, on the display panel, a plurality of light emitters, each of the plurality of light emitters including a light-emitting element and solution, respectively applying different voltages to the first electrode and the second electrode such that intervals between the light-emitting elements of the plurality of light emitters are more uniform on a plane compared to intervals between the light-emitting elements of the plurality of light emitters during the spraying of the plurality of light emitters, and respectively applying different voltages to the first electrode and the second electrode such that the light-emitting element is in contact with each of the first electrode and the second electrode.

In one or more embodiments, during the respectively applying of the different voltages to the first electrode and the second electrode such that intervals between the light-emitting elements of the plurality of light emitters are uniform, a first-1 voltage may be applied to the first electrode, and a first-2 voltage may be applied to the second electrode, and during the respectively applying of the different voltages to the first electrode and the second electrode such that the light-emitting element is in contact with each of the first electrode and the second electrode, a second-1 voltage may be applied to the first electrode, and a second-2 voltage may be applied to the second electrode.

In one or more embodiments, the first-1 voltage may be a direct current voltage.

In one or more embodiments, the first-1 voltage may be an alternating current voltage.

In one or more embodiments, a waveform of the first-1 voltage may change over time.

In one or more embodiments, the first-2 voltage may be a ground voltage.

In one or more embodiments, the second-1 voltage may be a direct current voltage.

In one or more embodiments, the second-2 voltage may be a ground voltage.

In one or more embodiments, the light-emitting element may include a first semiconductor layer, a second semiconductor layer, and an active layer between the first semiconductor layer and the second semiconductor layer.

In one or more embodiments, during the secondarily aligning of the plurality of light emitters, the first semiconductor layer may be in contact with the second electrode, and the second semiconductor layer may be in contact with the first electrode.

In one or more embodiments, a method of manufacturing an electronic device, the method including: manufacturing a display apparatus, the manufacturing including: disposing, on a jig part, a display panel including a first electrode and a second electrode; spraying, on the display panel, a plurality of light emitters, each of the plurality of light emitters including a light-emitting element and a solution; primarily aligning the plurality of light emitters by applying a first-1 voltage to the first electrode and applying a first-2 voltage to the second electrode; and secondarily aligning the plurality of light emitters by applying a second-1 voltage to the first electrode and applying a second-2 voltage to the second electrode; and communicatively coupling the display apparatus with a control circuit.

These and/or other aspects will become apparent and more readily appreciated from the following detailed description of the embodiments, the accompanying drawings, claims, and their equivalents.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic perspective view of a display apparatus according to one or more embodiments;

FIG. 2 is a schematic plan view of a portion of the display apparatus according to one or more embodiments;

FIG. 3 is a plan view showing an example of pixels in a display area of FIG. 1;

FIG. 4 is a plan view showing an example of pixels in a display area of FIG. 1;

FIG. 5 is a schematic cross-sectional view of the display apparatus according to one or more embodiments;

FIG. 6 is a schematic perspective view of a light emitter (e.g., light emitting element) according to one or more embodiments;

FIG. 7 is a schematic perspective view of an apparatus for manufacturing a display apparatus according to one or more embodiments;

FIG. 8 is a cross-sectional view of an inkjet part according to one or more embodiments;

FIG. 9 is a flowchart showing a method of manufacturing a display apparatus according to one or more embodiments;

FIG. 10 is a cross-sectional view of a portion of a display panel according to one or more embodiments;

FIGS. 11-13 are plan views of a portion of a display panel according to one or more embodiments;

FIG. 14 is a graph showing a waveform of a first-1 voltage applied to a first electrode according to one or more embodiments;

FIG. 15 is a cross-sectional view of a portion of a display panel according to one or more embodiments;

FIG. 16 is a graph showing a waveform of a first-1 voltage applied to a first electrode according to one or more embodiments;

FIG. 17 is a cross-sectional view of a portion of a display panel according to one or more embodiments; and

FIGS. 18 and 19 are graphs showing a waveform of a first-1 voltage applied to a first electrode according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects and features of the present disclosure, and methods for achieving them will be clarified with reference to embodiments described below in detail with reference to the drawings. However, the present disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the present disclosure is not necessarily limited thereto.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be concurrently (e.g., simultaneously) performed substantially and performed in the opposite order.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

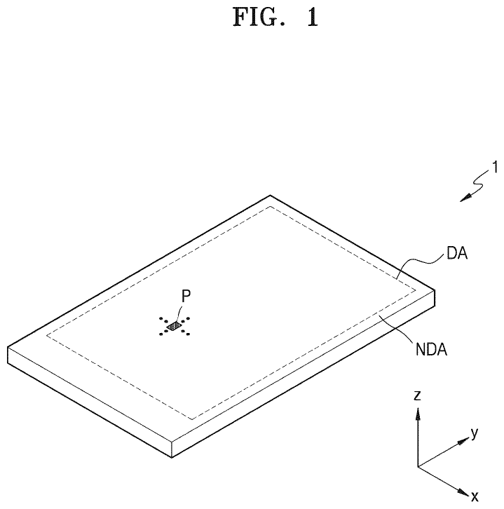

FIG. 1 is a schematic perspective view of a display apparatus 1 according to one or more embodiments.

Referring to FIG. 1, the display apparatus 1 may include a display area DA and a non-display area NDA around an edge or a periphery of the display area DA. The non-display area NDA may surround the display area DA. The display apparatus 1 may be configured to display images using light emitted from a plurality of pixels P arranged in the display area DA, and the non-display area NDA may be a region in which images are not displayed.

Although FIG. 1 shows that the display apparatus 1 includes a flat display surface, the present disclosure is not limited thereto. In one or more embodiments, the display apparatus 1 may include a three-dimensional display surface or a curved display surface.

In a case where the display apparatus 1 includes a three-dimensional display surface, the display apparatus 1 may include a plurality of display areas indicating different directions from each other, for example, may include a polygonal pillar-shaped display surface. In one or more embodiments, in a case where the display apparatus 1 includes a curved display surface, the display apparatus 1 may be implemented in various shapes such as a flexible, foldable, rollable display apparatus, and/or the like.

FIG. 1 shows the display apparatus 1 applicable to a mobile phone terminal. In one or more embodiments, an electronic module, a camera module, a power module, and/or the like mounted on a mainboard may be disposed in a bracket/case and/or the like together with the display apparatus 1 to configure a mobile phone terminal. Particularly, the display apparatus 1 according to one or more embodiments is applicable to large-sized electronic apparatuses such as televisions and monitors and small and medium-sized electronic apparatuses such as tablets, car navigation apparatuses, game consoles, and/or smartwatches.

Although it is shown in FIG. 1 that the display area DA of the display apparatus 1 is quadrangular, the shape of the display area DA may be circular, elliptical, or polygonal such as triangular or pentagonal.

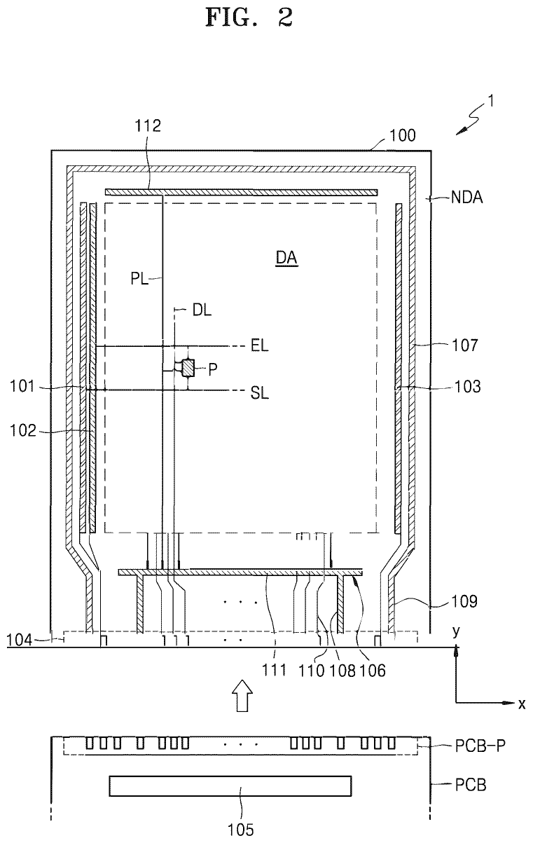

FIG. 2 is a schematic plan view of a portion of the display apparatus 1 according to one or more embodiments.

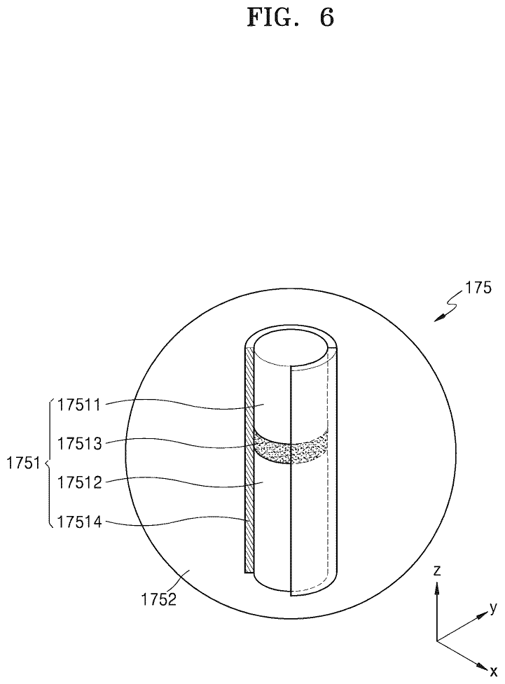

Referring to FIG. 2, the display apparatus 1 includes a plurality of pixels P disposed in the display area DA. Each of the plurality of pixels P may include a display element such as a light-emitting element 1751 (see FIG. 6). Each of the plurality of pixels P may emit, for example, red, green, blue, or white light from the light-emitting element 1751 (see FIG. 6). In the present specification, the pixel P may be understood as a pixel configured to emit red, green, blue, or white light.

Each of the plurality of pixels P may be electrically connected to outer circuits disposed in the non-display area NDA. A first scan driving circuit 101, a first emission driving circuit 102, a second scan driving circuit 103, a terminal 104, a data driving circuit 105, a first power supply line 106, and a second power supply line 107 may be disposed in the non-display area NDA.

The first scan driving circuit 101 may be configured to provide scan signals to each pixel P through a scan line SL. The first emission driving circuit 102 may be configured to provide emission control signals to each pixel P through an emission control line EL. The second scan driving circuit 103 may be disposed in parallel to the first scan driving circuit 101 with the display area DA therebetween. Some of the plurality of pixels P disposed in the display area DA may be electrically connected to the first scan driving circuit 101, and the others may be electrically connected to the second scan driving circuit 103. In one or more embodiments, a second emission driving circuit may be disposed in parallel to the first emission driving circuit 102 with the display area DA therebetween.

The first emission driving circuit 102 may be spaced (or may be apart) from the first scan driving circuit 101 in a first direction (e.g., an x axis direction) and disposed in the non-display area NDA. In one or more embodiments, the first emission driving circuit 102 may be alternately disposed with the first scan driving circuit 101 along a second direction (e.g., a y axis direction) crossing the first direction (e.g., the x axis direction).

The terminal 104 may be disposed on one side of a substrate 100. The terminal 104 may be exposed by not being covered by an insulating layer, and may be electrically connected to a printed circuit board PCB. A terminal PCB-P of the printed circuit board PCB may be electrically connected to the terminal 104 of the display apparatus 1. The printed circuit board PCB is configured to transfer signals of a controller or power to the display apparatus 1. Control signals generated by the controller may be respectively transferred to the first scan driving circuit 101, the first emission driving circuit 102, and the second scan driving circuit 103 through the printed circuit board PCB. The controller may be configured to respectively provide a first power voltage ELVDD and a second power voltage ELVSS to the first power supply line 106 and the second power supply line 107 through a first connection line 108 and a second connection line 109. The first power voltage ELVDD may be provided to the pixel P through a driving voltage line PL connected to the first power supply line 106, and the second power voltage ELVSS may be provided to an opposite electrode of the pixel P, connected to the second power supply line 107.

The data driving circuit 105 is electrically connected to a data line DL. A data signal of the data driving circuit 105 may be provided to each pixel P through a connection line 110 and the data line DL, wherein the connection line 110 is connected to the terminal 104, and the data line DL is connected to the connection line 110.

Although it is shown in FIG. 2 that the data driving circuit 105 is disposed on the printed circuit board PCB, the data driving circuit 105 may be disposed on the substrate 100 in one or more embodiments. As an example, the data driving circuit 105 may be disposed between the terminal 104 and the first power supply line 106.

The first power supply line 106 may include a first sub-line 111 and a second sub-line 112 extending in the first direction (e.g., the x axis direction) in parallel to each other with the display area DA therebetween. The second power supply line 107 may have a loop shape having one open side to be around (e.g., partially surround) the display area DA.

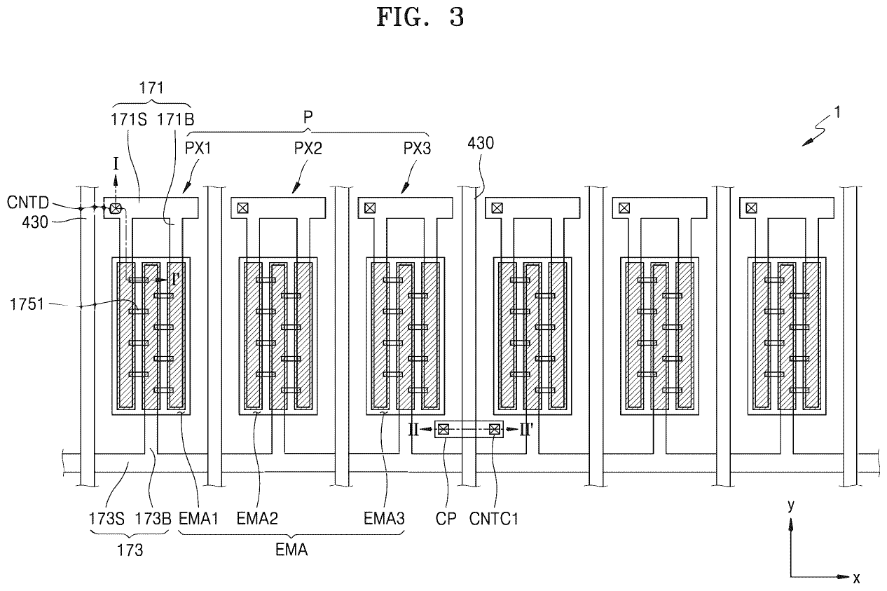

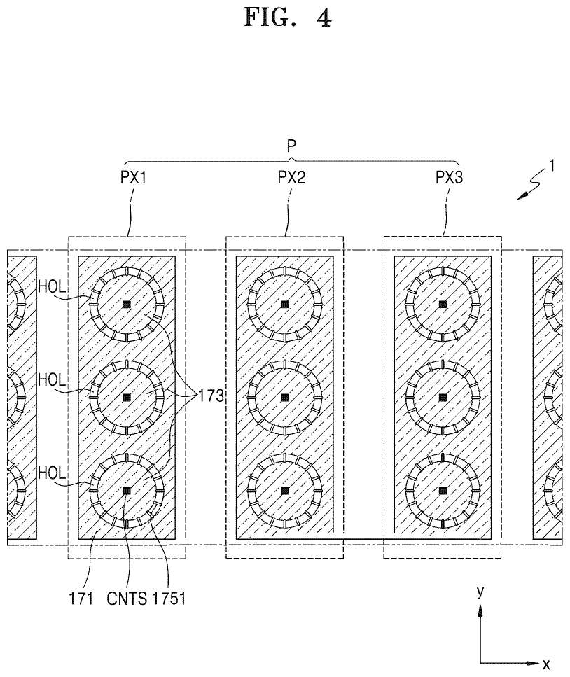

FIG. 3 is a plan view showing an example of pixels P in the display area DA of FIG. 1, and FIG. 4 is a plan view showing an example of pixels P in the display area DA of FIG. 1.

Referring to FIG. 3, each of the plurality of pixels P may include a first sub-pixel PX1, a second sub-pixel PX2, and a third sub-pixel PX3. The first sub-pixel PX1 may emit first light, the second sub-pixel PX2 may emit second light, and the third sub-pixel PX3 may emit third light. The first light may be red light, the second light may be green light, and the third light may be blue light, but the light is not limited thereto. The sub-pixels, that is, the first sub-pixel PX1, the second sub-pixel PX2, and the third sub-pixel PX3, may emit light of same color. In addition, although it is shown in FIG. 3 that the pixel P includes three sub-pixels, the present disclosure is not limited thereto.

The sub-pixels, that is, the first sub-pixel PX1, the second sub-pixel PX2, and the third sub-pixel PX3, may include an emission area EMA and a non-emission area. The first sub-pixel PX1 may include a first emission area EMA1, the second sub-pixel PX2 may include a second emission area EMA2, and the third sub-pixel PX3 may include a third emission area EMA3. The emission area EMA may be defined as a region in which the light-emitting element 1751 is disposed and from which light in a specific wavelength band is emitted. The non-emission area may be defined as a region other than the emission area EMA. The non-emission area may be a region in which the light-emitting element 1751 is not disposed, to which light emitted from the light-emitting element 1751 does not reach, and from which no light is emitted.

Each of the sub-pixels, that is, the first sub-pixel PX1, the second sub-pixel PX2, and the third sub-pixel PX3 may include a first electrode 171, a second electrode 173, and the light-emitting element 1751. The first electrode 171 may be a pixel electrode separated for each of the sub-pixels, that is, the first sub-pixel PX1, the second sub-pixel PX2, and the third sub-pixel PX3, and the second electrode 173 may be a common electrode commonly connected to the first sub-pixel PX1, the second sub-pixel PX2, and the third sub-pixel PX3. Alternatively, the first electrode 171 may be an anode of the light-emitting element 1751, and the other may be a cathode electrode of the light-emitting element 1751.

The first electrode 171 and the second electrode 173 may respectively include electrode stem portions 171S and 173S extending in the first direction (e.g., the x axis direction), and one or more electrode branch portions 171B and 173B extending and branching in the second direction (e.g., the y axis direction) from the electrode stem portions 171S and 173S. In this case, the first direction (e.g., the x axis direction) and the second direction (e.g., the y axis direction) may be directions crossing each other.

The first electrode 171 may include the first electrode stem portion 171S extending in the first direction (e.g., the x axis direction) and at least one first electrode branch portion 171B branching from the first electrode stem portion 171S and extending in the second direction (e.g., the y axis direction).

A first electrode stem portion 171S of one sub-pixel may be electrically separated from a first electrode stem portion 171S of a sub-pixel adjacent in the first direction (e.g., the x axis direction). A first electrode stem portion 171S of one sub-pixel may be spaced (or may be apart) from a first electrode stem portion 171S of a sub-pixeladjacent in the first direction (e.g., the x axis direction). The first electrode stem portion 171S may be connected to a thin-film transistor through a first electrode contact hole CNTD.

The first electrode branch portion 171B may be spaced (or may be apart) from the second electrode stem portion 173S in the second direction (e.g., the y axis direction). The first electrode branch portion 171B may be spaced (or may be apart) from the second electrode branch portion 173B in the first direction (e.g., the x axis direction).

The second electrode 173 may include the second electrode stem portion 173S extending in the first direction (e.g., the x axis direction) and the second electrode branch portion 173B branching from the second electrode stem portion 173S and extending in the second direction (the y axis direction).

A second electrode stem portion 173S of one sub-pixel may be connected to a second electrode stem portion 173S of a sub-pixel adjacent in the first direction (e.g., the x axis direction). The second electrode stem portion 173S may be disposed to cross the sub-pixels, that is, the first sub-pixel PX1, the second sub-pixel PX2, and the third sub-pixel PX3 in the first direction (e.g., the x axis direction).

The second electrode branch portion 173B may be spaced (or may be apart) from the first electrode stem portion 171S in the second direction (e.g., the y axis direction). The second electrode branch portion 173B may be spaced (or may be apart) from the first electrode branch portion 171B in the first direction (e.g., the x axis direction). The second electrode branch portion 173B may be disposed between the first electrode branch portions 171B in the first direction (e.g., the x axis direction).

Although it is shown in FIG. 3 that the first electrode branch portion 171B and the second electrode branch portion 173B extend in the second direction (e.g., the y axis direction), the present disclosure is not limited thereto. As an example, each of the first electrode branch portion 171B and the second electrode branch portion 173B may have a partially curved or bent shape, and may be disposed such that one electrode surrounds the other electrode as shown in FIG. 4. In FIG. 4, it is shown as an example that the second electrode 173 has a circular shape, the first electrode 171 is disposed to be around (e.g., to surround) the second electrode 173, a ring-shaped hole HOL is formed between the first electrode 171 and the second electrode 173, and the second electrode 173 receives a cathode voltage through a second electrode contact hole CNTS. That is, as long as at least partial regions of the first electrode 171 and the second electrode 173 are spaced (or may be apart) from and face each other and a space in which the light-emitting element 1751 may be disposed is formed between the first electrode 171 and the second electrode 173, each of the first electrode branch portion 171B and the second electrode branch portion 173B may be formed in any shape.

The light-emitting element 1751 may be disposed between the first electrode 171 and the second electrode 173. One end of the light-emitting element 1751 may be electrically connected to the first electrode 171, and the other end may be electrically connected to the second electrode 173. The plurality of light-emitting elements 1751 may be spaced (or may be apart) from each other. The plurality of light-emitting elements 1751 may be aligned to be substantially parallel to each other.

The light-emitting element 1751 may have a shape such as a rod, a wire, a tube, and/or the like. As an example, the light-emitting element 1751 may be formed in a cylindrical or rod shape as shown in FIG. 6. The shape of the light-emitting element 1751 is not limited thereto and may have a polygonal prism shape such as a cube, rectangular parallelepiped, or hexagonal prism, or may have a shape that extends in one direction but has a partially inclined outer surface. A length h of the light-emitting element 1751 may be in a range of about 0.5 μm to about 9 μm, or about 1 μm to about 6 μm, and preferably a range of about 3 μm to about 5 μm. In addition, a diameter of the light-emitting element 1751 may be in a range of about 0.1 μm to about 0.9 μm, and an aspect ratio of the light-emitting element 1751 may be about 5 to about 10.

The light-emitting element 1751 of the first sub-pixel PX1 may emit first light, the light-emitting element 1751 of the second sub-pixel PX2 may emit second light, and the light-emitting element 1751 of the third sub-pixel PX3 may emit third light. The first light may be red light whose central wavelength band is in a range of about 620 nm to about 752 nm, the second light may be green light whose central wavelength band is in a range of about 495 nm to about 570 nm, and the third light may be blue light whose central wavelength band is in a range of about 450 nm to about 495 nm. Alternatively, the light-emitting element 1751 of the first sub-pixel PX1, the light-emitting element 1751 of the second sub-pixel PX2, and the light-emitting element 1751 of the third sub-pixel PX3 may emit light of substantially the same color.

External banks 430 may be disposed between the sub-pixels, that is, the first sub-pixel PX1, the second sub-pixel PX2, and the third sub-pixel PX3. The external banks 430 may extend along the second direction (e.g., the y axis direction). A length in the first direction (e.g., the x axis direction) of each of the sub-pixels, that is, the first sub-pixel PX1, the second sub-pixel PX2, and the third sub-pixel PX3 may be defined by a distance between the external banks 430.

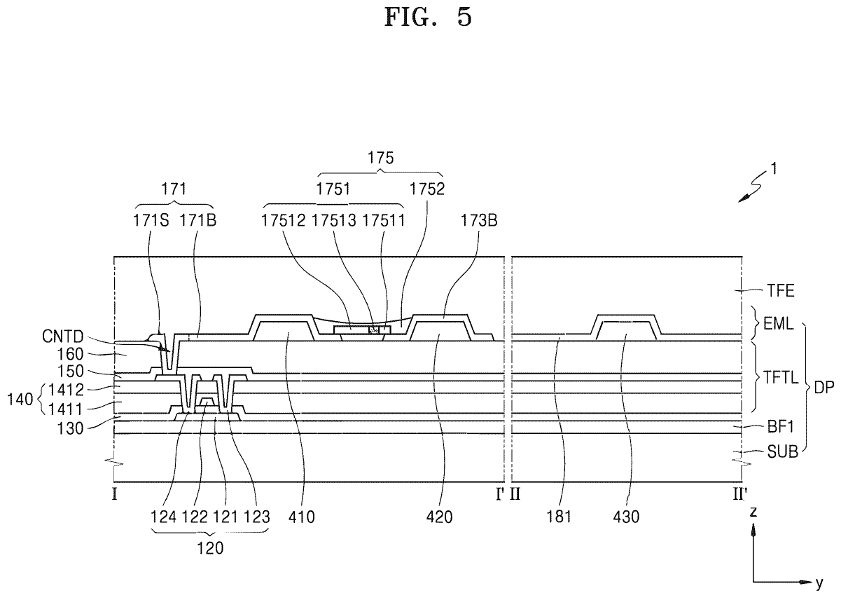

FIG. 5 is a schematic cross-sectional view of the display apparatus 1 according to one or more embodiments, and FIG. 6 is a schematic perspective view of an emission portion 175 according to one or more embodiments.

Specifically, FIG. 5 corresponds to a cross-section of the display apparatus 1 taken along lines I-I′ and II-II′ of FIG. 3.

Referring to FIGS. 5 and 6, the display apparatus 1 may include the display panel DP and an encapsulation layer TFE. Specifically, the display panel DP may include a substrate SUB, a first buffer layer BF1, a thin-film transistor layer TFTL, and a light-emitting element layer EML.

The first buffer layer BF1 may be formed on one surface of the substrate SUB. The first buffer layer BF1 may be formed on one surface of the substrate SUB to protect thin-film transistors 120 and the light-emitting element layer EML of a display layer from moisture penetrating through the substrate SUB vulnerable to moisture transmission. The first buffer layer BF1 may include a plurality of inorganic layers that are alternately stacked. As an example, the first buffer layer BF1 may include a multi-layer in which one or more inorganic layers of a silicon nitride layer, a silicon oxynitride layer, a silicon oxide layer, a titanium oxide layer, and an aluminum oxide layer are alternately stacked. The first buffer layer BF1 may be omitted.

The thin-film transistor layer TFTL may include the thin-film transistors 120, a first insulating layer 130, an interlayer insulating layer 140, a protective layer 150, and a planarization layer 160.

The thin-film transistor 120 may be located on the first buffer layer BF1. The thin-film transistor 120 may include an active layer 121, a gate electrode 122, a source electrode 123, and a drain electrode 124. Although FIG. 5 shows, as an example, the thin-film transistor 120 is formed as a top-gate transistor in which the gate electrode 122 of the thin-film transistor 120 is located over the active layer 121, a gate structure of the present disclosure is not limited thereto. That is, the thin-film transistors 120 may be formed as bottom-gate transistors in which the gate electrode 122 is located below the active layer 121, or formed as double-gate transistors in which the gate electrodes 122 are located both over and below the active layer 121.

The active layer 121 may be disposed on the first buffer layer BF1. The active layer 121 may include an oxide semiconductor and/or a silicon semiconductor. In the case where the active layer 121 includes an oxide semiconductor, the semiconductor layer 121 may include, for example, an oxide of indium (In), gallium (Ga), stannum (Sn), zirconium (Zr), vanadium (V), hafnium (Hf), cadmium (Cd), germanium (Ge), chromium (Cr), titanium (Ti), and/or zinc (Zn). As an example, the active layer 121 may include an ITZO(InSnZnO), an IGZO(InGaZnO), and/or the like. In the case where the active layer 121 includes a silicon semiconductor, the semiconductor layer 121 may include, for example, amorphous silicon (a-Si) or a low-temperature polycrystalline silicon (LTPS) formed by crystalizing amorphous silicon (a-Si).

In one or more embodiments, a light-blocking layer may be disposed on the first buffer layer BF1. The light-blocking layer may be disposed to correspond to the thin-film transistor 120 and thus may prevent the gate electrode 122, the source electrode 123, and the drain electrode 124 of the thin-film transistor 120 from being viewed to the outside. A voltage may be applied to the light-blocking layer. As an example, the light-blocking layer may be connected to the source electrode 123 or the drain electrode 124 of the thin-film transistor 120. Because the light-blocking layer is supplied with a voltage by cooperatively operating with the electrical potential of the source electrode 123 or the drain electrode 124 of the thin-film transistor 120, the thin-film transistor 120 of the display apparatus may be stabilized through this. In one or more embodiments, the light-blocking layer may be connected to a separate wiring without being connected to the source electrode 123 or the drain electrode 124 of the thin-film transistor 120.

The first insulating layer 130 may be disposed on the active layer 121 and the first buffer layer BF1. The first insulating layer 130 may include at least one inorganic insulating material selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂). The first insulating layer 130 may include a single layer or a multi-layer including the inorganic insulating material.

The gate electrode 122 and a gate line may be disposed on the first insulating layer 130. The gate electrode 122 may overlap the active layer 121 and may be disposed on the first insulating layer 130. The gate electrode 122 and the gate line may include at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals.

A first interlayer insulating layer 1411 may be disposed on the gate electrode 122 and the first insulating layer 130. The first interlayer insulating layer 1411 may include at least one inorganic insulating material selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂). The first interlayer insulating layer 1411 may include a single layer or a multi-layer including the inorganic insulating material.

In one or more embodiments, a storage capacitor may be disposed on the first insulating layer 130. The storage capacitor may include a lower electrode and an upper electrode, may overlap the thin-film transistor 120. The lower electrode of the storage capacitor may be integrally disposed with the gate electrode 122 of the thin-film transistor 120. In one or more embodiments, the storage capacitor may not overlap the thin-film transistor 120, and the lower electrode may be an independent element separate from the gate electrode 122 of the thin-film transistor 120.

A second interlayer insulating layer 1412 may be disposed on the first interlayer insulating layer 1411. The second interlayer insulating layer 1412 may include at least one inorganic insulating material selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂). The second interlayer insulating layer 1412 may include a single layer or a multi-layer including the inorganic insulating material.

The source electrode 123, and the drain electrode 124 may be disposed on the second interlayer insulating layer 1412. Each of the source electrode 123 and the drain electrode 124 may be connected to the active layer 121 through a contact hole passing through the interlayer insulating layer 140 (1411, 1412) and the first insulating layer 130. The source electrode 123 and the drain electrode 124 may each include a conductive material including molybdenum (Mo), aluminum (Al), copper (Cu), and/or titanium (Ti) and include a single layer or a multi-layer including the above materials. As an example, the source electrode 123 and the drain electrode 124 may have a multi-layered structure of Ti/Al/Ti.

The protective layer 150 may be disposed on the source electrode 123 and the drain electrode 124 and on the second interlayer insulating layer 1412 to insulate the thin-film transistor 120. The protective layer 150 may include at least one inorganic insulating material selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂). The protective layer 150 may include a single layer or a multi-layer including the inorganic insulating material.

The planarization layer 160 may be disposed on the protective layer 150. The planarization layer 160 may have a flat upper surface such that an electrode disposed thereon is formed flat. The planarization layer 160 may include an organic material such as acrylic resin, epoxy resin, phenolic resin, polyamide resin, and/or polyimide resin.

The light-emitting element layer EML is disposed on the thin-film transistor layer TFTL. The light-emitting element layer EML may include a first inner bank 410, a second inner bank 420, an outer bank 430, a first electrode 171, and a second electrode 173, and an emission portion 175.

The first inner bank 410, the second inner bank 420, and the outer bank 430 may be disposed on the planarization layer 160. The first inner bank 410, the second inner bank 420, and the outer bank 430 may protrude with respect to the upper surface of the planarization layer 160. The first inner bank 410, the second inner bank 420, and the outer bank 430 may have a trapezoidal cross-section but are not limited thereto. The first inner bank 410, the second inner bank 420, and the outer bank 430 may include a lower surface in contact with the upper surface of the planarization layer 160, an upper surface facing the lower surface, and lateral surfaces between the upper surface and the lower surface. The lateral surfaces of the first inner bank 410, the lateral surfaces of the second inner bank 420, and the lateral surfaces of the outer bank 430 may be formed to be inclined.

The first inner bank 410 and the second inner bank 420 may be spaced (or may be apart) from each other. The first inner bank 410 and the second inner bank 420 may include an organic layer such as acrylic resin, epoxy resin, phenolic resin, polyamide resin, and/or polyimide resin.

The first electrode branch portion 171B may be disposed on the first inner bank 410, and the second electrode branch portion 173B may be disposed on the second inner bank 420. The first electrode branch portion 171B may be connected to the first electrode stem portion 171S, and the first electrode stem portion 171S may be connected to the drain electrode 124 of the thin-film transistor 120 through the first electrode contact hole CNTD. Accordingly, the first electrode 171 may receive a voltage from the drain electrode 124 of the thin-film transistor 120.

The first electrode 171 and the second electrode 173 may include a conductive material with high reflectivity. As an example, the first electrode 171 and the second electrode 173 may include a metal such as silver (Ag), copper (Cu), and/or aluminum (AI). Accordingly, from among light emitted from the light-emitting element 1751, light progressing to the first electrode 171 and the second electrode 173 may be reflected by the first electrode 171 and the second electrode 173 and travel to an upper side of the light-emitting element 1751.

The emission portion 175 may be disposed between the first electrode 171 and the second electrode 173. The emission portion 175 may include the light-emitting element 1751 and a solution 1752.

The light-emitting element 1751 may include a first semiconductor layer 17511, a second semiconductor layer 17512, an active layer 17513, and an insulating layer 17514.

The first semiconductor layer 17511 may be, for example, an n-type semiconductor having a first conductive type. The first semiconductor layer 17511 may include n-type doped AlGaInN, GaN, AlGaN, InGaN, AlN, and/or InN. As an example, in the case where the light-emitting element 1751 emits light in a blue wavelength band, the first semiconductor layer 17511 may include a semiconductor material having a chemical formular of AlₓGa_{y}In_{1-x-y}N(0≤x≤1,0≤y≤1, 0≤x+y≤1). The first semiconductor layer 17511 may be doped with a first conductive type dopant such as Si, Ge, and/or Sn. As an example, the first semiconductor layer 17511 may be an n-GaN doped with an n-type Si.

The second semiconductor layer 17512 may be, for example, a p-type semiconductor having a second conductive type. The second semiconductor layer 17512 may include p-type doped AlGaInN, GaN, AlGaN, InGaN, AlN, and/or InN. As an example, in the case where the light-emitting element 1751 emits light in a blue or green wavelength band, the second semiconductor layer 17512 may include a semiconductor material having a chemical formular of AlₓGa_{y}In_{1-x-y}N(0≤x≤1,0≤y≤1, 0≤x+y≤1). The second semiconductor layer 17512 may be doped with a second conductive-type dopant such as Mg, Zn, Ca, Se, and/or Ba. In one or more embodiments, the second semiconductor layer 17512 may be a p-GaN doped with a p-type Mg.

The active layer 17513 may be disposed between the first semiconductor layer 17511 and the second semiconductor layer 17512. The active layer 17513 may include a material of a single or multiple quantum well structure. In the case where the active layer 17513 may include a material of a multiple quantum well structure, the active layer 17513 may have a structure in which quantum layers and well layers are alternately stacked. Alternatively, the active layer 17513 may have a structure in which semiconductor materials having a large band gap energy and semiconductor materials having a small band gap energy are alternately stacked, or may include Group III to Group 5 semiconductor materials according to a wavelength band of emitted light.

The active layer 17513 may emit light due to combining of an electron-hole pair according to electrical signals applied through the first semiconductor layer 17511 and the second semiconductor layer 17512. Light emitted by the active layer 17513 is not limited to light in a blue wavelength band. The active layer 17513 may emit light in a red or green wavelength band. As an example, in the case where the active layer 17513 emits light in a blue wavelength band, the active layer 17513 may include a material such as AlGaN and/or AlGaInN. Particularly, in the case where the active layer 17513 has a multiple quantum-well structure in which quantum layers and well layers are alternately stacked, the quantum layer may include a material such as AlGaN and/or AlGaInN, and the well layer may include a material such as GaN and/or AlInN. As an example, because the active layer 17513 includes AlGaInN as a quantum layer and includes AlInN as a well layer, the active layer 17513 may emit blue light having a central wavelength band in a range of about 450 nm to about 495 nm as described above.

Light emitted from the active layer 17513 may be emitted to two lateral sides as well as an outer surface in a lengthwise direction of the light-emitting element 1751. That is, light emitted from the active layer 17513 is not restricted in direction.

The insulating layer 17514 is disposed to be around (e.g., to surround) the outer surfaces (e.g., outer peripheral or circumferential surfaces) of the first semiconductor layer 17511, the second semiconductor layer 17512, and the active layer 17513. The insulating layer 17514 protects the first semiconductor layer 17511, the second semiconductor layer 17512, and the active layer 17513. The insulating layer 17514 may be formed to expose two opposite ends in the lengthwise direction of the light-emitting element 1751. That is, one end of the first semiconductor layer 17511 and one end of an electrode layer on the second semiconductor layer 17512 may be exposed by not being covered by the insulating layer 17514. The insulating layer 17514 may cover a portion of the first semiconductor layer 17511, and only an outer surface (e.g., an outer peripheral or circumferential surface) of a portion of the second semiconductor layer 17512, including the active layer 17513, or cover only an outer surface (e.g., an outer peripheral or circumferential surface) of a portion of the electrode layer on the second semiconductor layer 17512.

The insulating layer 17514 may include materials having insulating properties, for example, silicon oxide (SiOₓ), silicon nitride (SiNₓ), silicon oxynitride (SiOₓN_{y}), aluminum nitride (AlN), aluminum oxide (Al₂O₃), and/or the like. The insulating layer 17514 may prevent electrical short-circuit that may occur in the case where the active layer 17513 is in direct contact with the first electrode 171 and the second electrode 173 through which an electrical signal is transferred to the light-emitting element 1751. In addition, because the insulating layer 17514 protects the outer surface (e.g., the outer peripheral or circumferential surface) of the light-emitting element 1751 including the active layer 17513, deterioration in light emission efficiency may be prevented.

The solution 1752 may be disposed to be around (e.g., to surround) the light-emitting element 1751. The solution 1752 may include a dispersing solvent. As an example, the solution 1752 may include at least one of acetone, water, alcohol, and/or toluene. However, this is just an example, and the material of the solution 1752 is not limited thereto. As long as the solution 1752 has a high volatilization performance without having physical or chemical influences on the light-emitting element 1751, the solution 1752 may be used without limitation.

The light-emitting element layer EML according to one or more embodiments may be formed by applying a voltage between the first electrode 171 and the second electrode 173 formed over the substrate SUB to form an electric field, then dropping the emission portion 175 including the light-emitting element 1751 and the solution 1752 on the first electrode 171 and the second electrode 173, and aligning the light-emitting elements 1751 on the first electrode 171 and the second electrode 173 using the electric field.

The encapsulation layer TFE may be disposed on the light-emitting element layer EML. The encapsulation layer TFE may include at least one inorganic encapsulation layer and at least one organic encapsulation layer. In one or more embodiments, the encapsulation layer TFE may include a first inorganic encapsulation layer, a second inorganic encapsulation layer, and an organic encapsulation layer disposed between the first inorganic encapsulation layer and the second inorganic encapsulation layer. The first and second inorganic encapsulation layers may include at least one inorganic insulating material selected from among aluminum oxide, titanium oxide, tantalum oxide, hafnium oxide, zinc oxide, silicon oxide, silicon nitride, silicon oxynitride, and the like. The organic encapsulation layer may include a polymer-based material. The polymer-based material may include an acryl-based resin, an epoxy-based resin, polyimide, and/or polyethylene. In one or more embodiments, the encapsulation layer TFE may be provided as an encapsulation substrate.

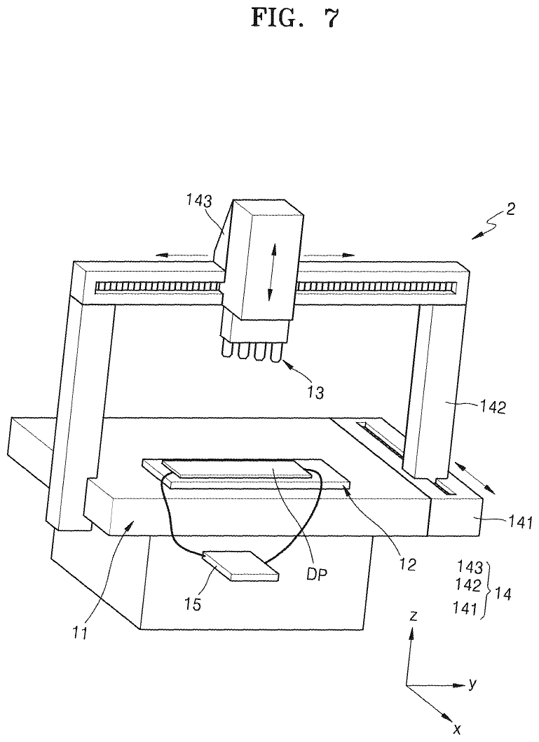

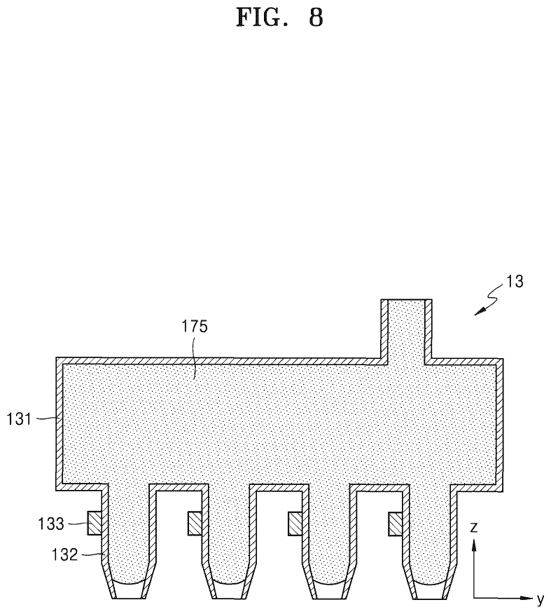

FIG. 7 is a schematic perspective view of an apparatus 2 for manufacturing a display apparatus according to one or more embodiments, and FIG. 8 is a cross-sectional view of an inkjet part 13 according to one or more embodiments.

Referring to FIGS. 7 and 8, in the apparatus 2 for manufacturing a display apparatus, the emission portion 175 may be disposed on the display panel DP.

The apparatus 2 for manufacturing a display apparatus may include a supporter 11, a jig part 12, an inkjet part 13, a moving part 14, and a voltage applying part 15.

The supporter 11 may support the jig part 12, the inkjet part 13, the moving part 14, and the voltage applying part 15. The supporter 11 may include a material having high strength and include a flat surface. Accordingly, the supporter 11 may stably support the jig part 12.

The jig part 12 may be disposed on the supporter 11, and the display panel DP may sit on the jig part 12. The jig part 12 may include a flat surface. The display panel DP may sit on the jig part 12, and the jig part 12 may stably support the display panel DP.

The inkjet part 13 may include a chamber 131, a nozzle part 132, and a spray adjustor 133. The chamber 131 may accommodate the emission portion 175. The emission portion 175 may be stored inside the chamber 131. The shape of the chamber 131 shown in FIGS. 7 and 8 is provided as an example and not limited thereto.

The nozzle part 132 may spray the emission portion 175 to the display panel DP. The nozzle part 132 may be connected to the chamber 131 to face the display panel DP. The inner space of the chamber 131 and the inner space of the nozzle part 132 may communicate with each other. The nozzle part 132 may be provided in plurality. As an example, as shown in FIGS. 7 and 8, the plurality of nozzle parts 132 may be arranged in a line. However, this is just an example, and the number and arrangement of nozzle parts 132 are not limited thereto.

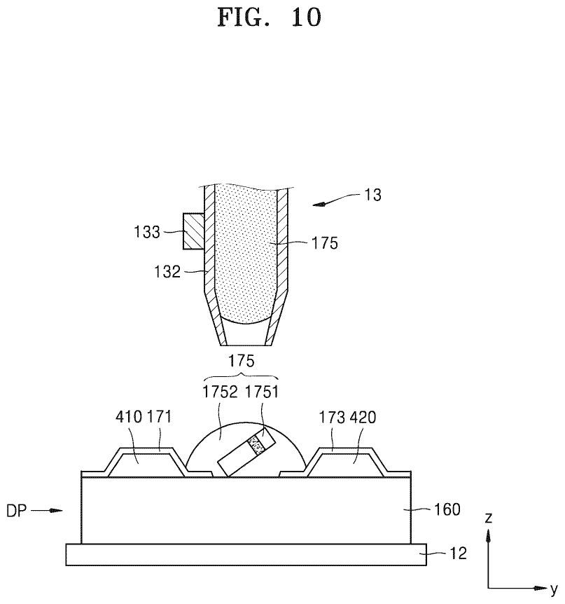

The spray adjustor 133 may adjust the amount of emission portion 175 sprayed by the nozzle part 132. The spray adjustor 133 may be disposed on the nozzle part 132. The spray adjustor 133 may be provided in a number corresponding to the number of nozzle parts 132. As an example, in the case where four nozzle parts 132 are provided, four spray adjustors 133 may be provided. The spray adjustor 133 is described below in detail with reference to FIG. 10.

The moving part 14 may connect the supporter 11 and the inkjet part 13 to each other and move the inkjet part 13 over the jig part 12. The moving part 14 may move the inkjet part 13 in the first direction (e.g., the x axis direction), the second direction (e.g., the y axis direction), and a third direction (e.g., a z axis direction). Here, the first direction (e.g., the x axis direction), the second direction (e.g., the y axis direction), and the third direction (e.g., the z axis direction) may be directions crossing one another. In addition, the third direction (e.g., the z axis direction) may be parallel to a direction in which gravity acts. The moving part 14 may include a first moving part 141, a second moving part 142, and a third moving part 143.

The first moving part 141 may move the inkjet part 13 in the first direction (e.g., the x axis direction). The first moving part 141 may be fixed to the supporter 11 and connected to the second moving part 142. The first moving part 141 may linearly reciprocate the second moving part 142. The first moving part 141 may include a linear motor. The second moving part 142 and the supporter 11 may be slidably connected to each other. Because the first moving part 141 provides power to the second moving part 142, the second moving part 142 may move in the first direction (e.g., the x axis direction) relative to the supporter 11.

The second moving part 142 may move the inkjet part 13 in the second direction (e.g., the y axis direction). The second moving part 142 may linearly reciprocate the third moving part 143. The second moving part 142 may include a linear motor. Because the second moving part 142 provides power to the third moving part 143, the third moving part 143 may move in the second direction (e.g., the y axis direction) relative to the supporter 11.

The third moving part 143 may move the inkjet part 13 in the third direction (e.g., the z axis direction). The third moving part 143 may include a linear motor. Because the third moving part 143 provides power to the inkjet part 13, the inkjet part 13 may move in the third direction (e.g., the z axis direction) relative to the supporter 11.

The voltage applying part 15 may be electrically connected to the display panel DP and may apply a voltage. The voltage applying part 15 may supply power to the display panel DP. The voltage applying part 15 may apply different voltages to the first electrode 171 (see FIG. 3) and the second electrode 173 (see FIG. 3), respectively.

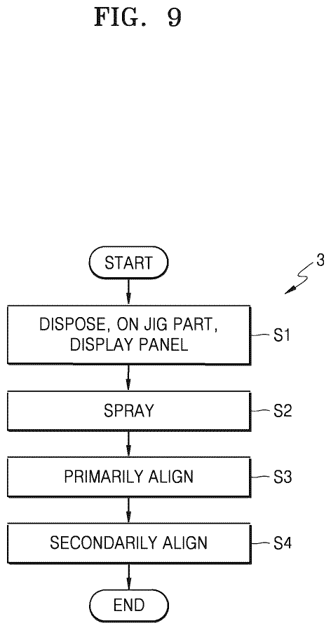

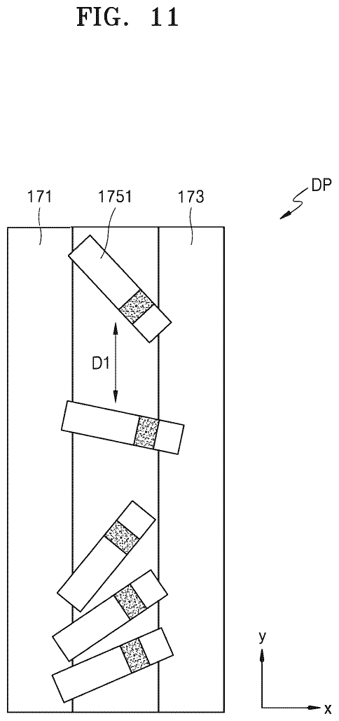

FIG. 9 is a flowchart showing a method 3 of manufacturing a display apparatus according to one or more embodiments, FIG. 10 is a cross-sectional view of a portion of the display panel DP according to one or more embodiments, and FIGS. 11-13 are plan views of a portion of the display panel DP according to one or more embodiments.

Referring to FIGS. 9 to 13, the method 3 of manufacturing a display apparatus may include disposing the display panel DP on the jig part 12 (S1), spraying (S2), primary aligning (S3), and secondary aligning (S4).

First, referring to FIGS. 9-11, disposing the display panel DP on the jig part 12 (S1), and spraying (S2) may be known.

The display panel DP including the first electrode 171 and the second electrode 173 may be disposed on the jig part 12. The display panel DP may sit on the jig part 12.

The inkjet part 13 may spray the emission portion 175 on the display panel DP. The amount of spraying the emission portion 175 may be adjusted according to an electrical signal applied to the spray adjustor 133. As an example, the amount of spraying the emission portion 175 may be adjusted according to the magnitude of a voltage applied to the spray adjustor 133.

As an example, the spray adjustor 133 may include a piezoelectric element. The piezoelectric element may receive an electrical signal to generate a pressure to the nozzle part 132. Accordingly, the volume inside the nozzle part 132 is reduced, and a pressure inside the nozzle part 132 may increase. Accordingly, the emission portion 175 inside the nozzle part 132 may be sprayed toward the display panel DP.

As an example, the spray adjustor 133 may include a thermoelectric element. The thermoelectric element may receive an electrical signal to emit heat to the nozzle part 132. Accordingly, the temperature inside the nozzle part 132 may increase, and a pressure inside the nozzle part 132 may increase. Accordingly, the emission portion 175 inside the nozzle part 132 may be sprayed toward the display panel DP.

However, this is just an example, and the method by which the spray adjustor 133 adjusts the amount of spraying the emission portion 175 is not limited thereto.

The emission portion 175 sprayed by the nozzle part 132 of the inkjet part 13 may be disposed on the planarization layer 160, the first electrode 171, and the second electrode 173. The emission portion 175 may be disposed between the first inner bank 410 and the second inner bank 420. The solution 1752 of the emission portion 175 may be in contact with the first electrode 171, the second electrode 173, and the light-emitting element 1751. The light-emitting element 1751 may float in the solution 1752.

The spraying of the emission portion 175 may be repeated multiple times. That is, the spraying (S2) may include spraying a plurality of light emitters 175 each including the light-emitting element 1751 and the solution 1752 on the display panel DP. Accordingly, as shown in FIG. 11, the plurality of light-emitting elements 1751 may be disposed on the first electrode 171 and the second electrode 173.

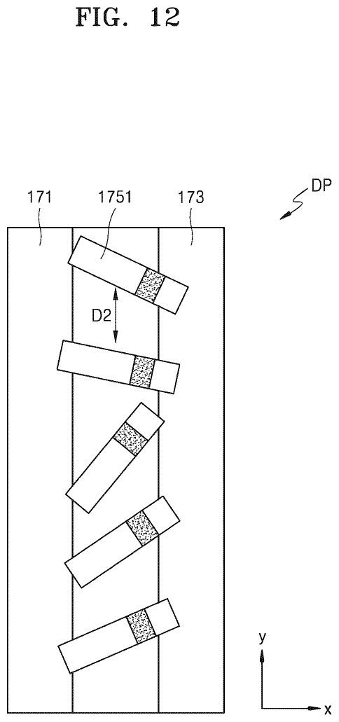

Referring to FIG. 12, the primary aligning (S3) may be known. The primary aligning (S3) may include applying a first-1 voltage to the first electrode 171 and applying a first-2 voltage to the second electrode 173 to align the plurality of light emitters 175. The first-1 voltage and the first-2 voltage may be different voltages from each other. Electro wetting technology is applicable to the primary aligning (S3).

It is known that an interval D2 between the plurality of light-emitting elements 1751 during the primary aligning (S3) shown in FIG. 12 is more uniform than an interval D1 between the plurality of light-emitting elements 1751 during the spraying (S2) shown in FIG. 11. That is, compared to the spraying S2, the primary aligning (S3) may be an operation of applying different voltages to the first electrode 171 and the second electrode 173 such that an interval between the plurality of light-emitting elements 1751 is uniform in a plan view (when viewed in a direction perpendicular to the substrate SUB (see FIG. 5)).

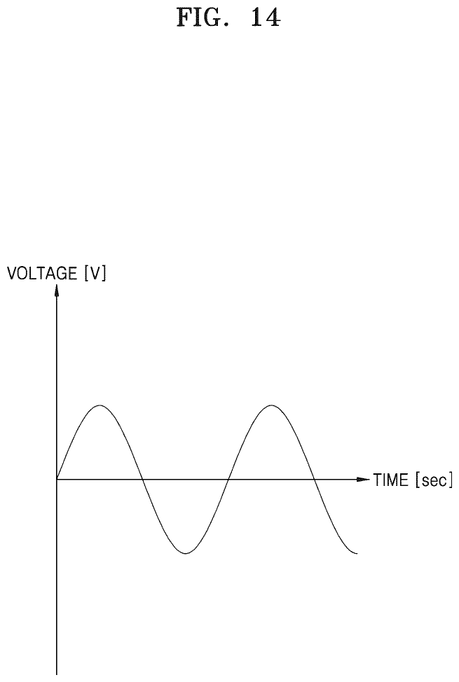

The first-1 voltage and the first-2 voltage are described specifically below with reference to FIGS. 14-19.

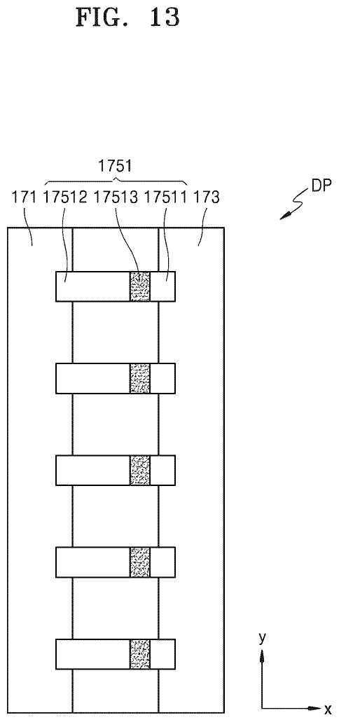

Referring to FIG. 13, the secondary aligning (S4) may be known. The secondary aligning (S4) may include applying a second-1 voltage to the first electrode 171 and applying a second-2 voltage to the second electrode 173 to align the plurality of light emitters 175. The second-1 voltage and the second-2 voltage may be different voltages from each other. As an example, the first-1 voltage, the first-2 voltage, the second-1 voltage, and the second-2 voltage may be different voltages from each other.

As an example, the second-1 voltage may be a direct current voltage, and the second-2 voltage may be a ground voltage. Accordingly, an electric field may be formed between the first electrode 171 and the second electrode 173. The plurality of light-emitting elements 1751 may be aligned on the first electrode 171 and the second electrode 173 by the electric field. As an example, in the secondary aligning (S4), the first semiconductor layer 17511 may be in contact with the second electrode 173, and the second semiconductor layer 17512 may be in contact with the first electrode 171. The active layer 17513 may be disposed between the first electrode 171 and the second electrode 173. That is, the secondary aligning (S4) may be an operation of respectively applying different voltages to the first electrode 171 and the second electrode 173 such that the light-emitting element 1751 is in contact with the first electrode 171 and the second electrode 173.

However, this is just an example, and the second-1 voltage may be a ground voltage, and the second-2 voltage may be a direct current voltage. The first semiconductor layer 17511 may be in contact with the first electrode 171, and the second semiconductor layer 17512 may be in contact with the second electrode 173.

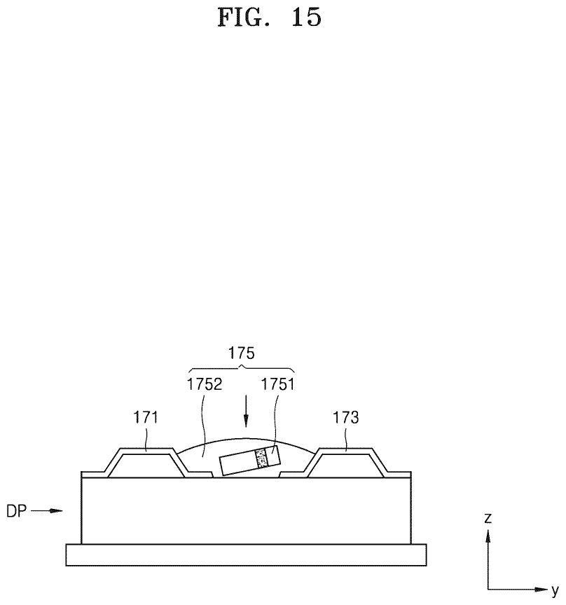

FIG. 14 is a graph showing a waveform of the first-1 voltage applied to the first electrode 171 according to one or more embodiments, and FIG. 15 is a cross-sectional view of a portion of the display panel DP according to one or more embodiments.

Specifically, FIG. 14 is a graph showing a waveform of the first-1 voltage in the primary aligning (S3), and FIG. 15 is a view showing the shape of the emission portion 175 when the waveform of the first-1 voltage is the graph shown in FIG. 14.

In FIG. 14, a horizontal axis represents time and the unit is seconds [sec], and a vertical axis represents voltage and the unit is volts [V].

Referring to FIG. 14, in the primary aligning (S3), the first-1 voltage may be an alternating current voltage. In this case, the first-2 voltage may be a ground voltage. As an example, the waveform of the first-1 voltage may be a sine function, and the first-2 voltage may be 0 [V]. However, this is just an example, and the waveform of the first-1 voltage may be a cos function.

Referring to FIG. 15, because an alternating current voltage is applied to the first-1 voltage, and a direct current voltage is applied to the first-2 voltage, the emission portion 175 may be closely attached to the display panel DP. That is, the solution 1752 and the light-emitting element 1751 may be closely attached to the first electrode 171 and the second electrode 173. In this case, the curvature of the upper surface of the solution 1752 may be reduced.

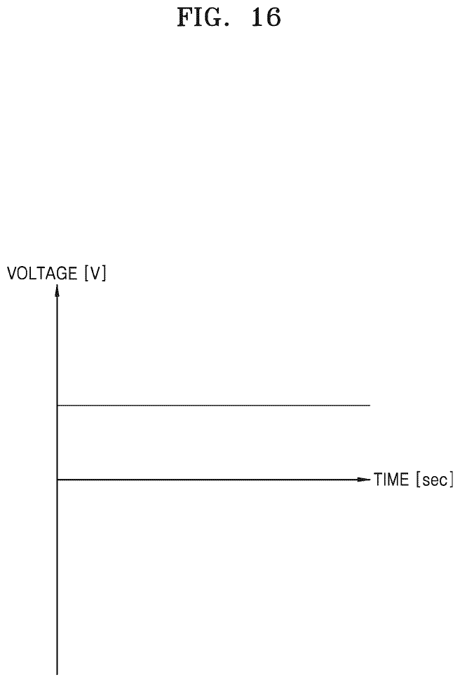

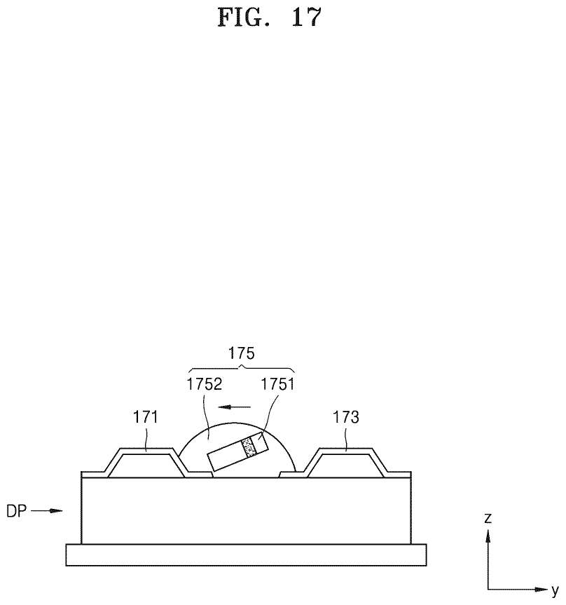

FIG. 16 is a graph showing a waveform of the first-1 voltage applied to the first electrode 171 according to one or more embodiments, and FIG. 17 is a cross-sectional view of a portion of the display panel DP according to one or more embodiments.

Specifically, FIG. 16 is a graph showing a waveform of the first-1 voltage in the primary aligning (S3), and FIG. 17 is a view showing the shape of the emission portion 175 when the waveform of the first-1 voltage is the graph shown in FIG. 16.

In FIG. 16, a horizontal axis represents time and the unit is seconds [sec], and a vertical axis represents voltage and the unit is volts [V].

Referring to FIG. 16, in the primary aligning (S3), the first-1 voltage may be a direct current voltage. In this case, the first-2 voltage may be a ground voltage. As an example, the first-1 voltage may be a constant positive value, and the first-2 voltage may be 0 [V].

Referring to FIG. 17, because a direct current voltage is applied to the first-1 voltage, and a ground voltage is applied to the first-2 voltage, the emission portion 175 may move in the second direction. As an example, as shown in FIG. 17, the solution 1752 and the light-emitting element 1751 may move in a direction facing the first electrode 171. However, this is just an example, and unlike FIG. 17, the emission portion 175 may move in a direction away from the first electrode 171.

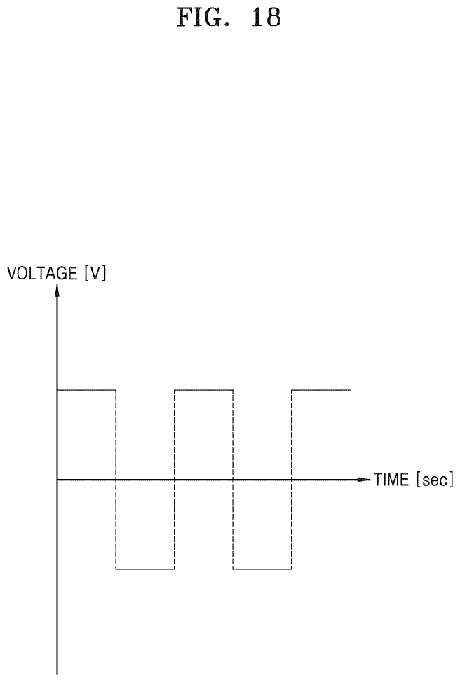

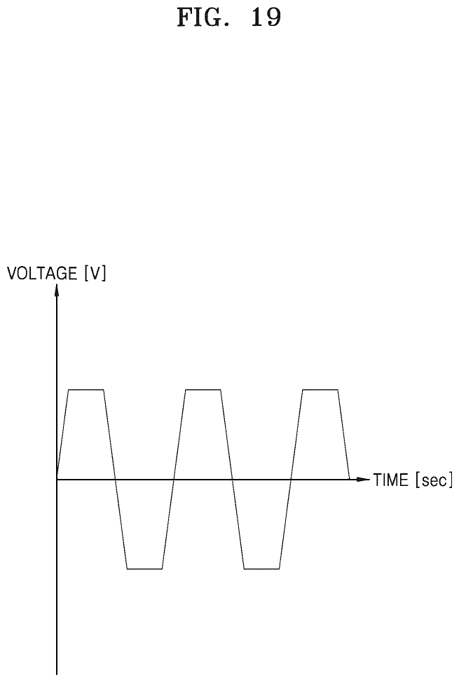

FIGS. 18 and 19 are graphs showing a waveform of a first-1 voltage applied to the first electrode 171 according to one or more embodiments.

Specifically, FIGS. 18 and 19 are graphs showing the waveform of the first-1 voltage in the primary aligning (S3).

In FIGS. 18 and 19, a horizontal axis represents time and the unit is seconds [sec], and a vertical axis represents voltage and the unit is volts [V].

Referring to FIG. 18, in the primary aligning (S3), the waveform of the first-1 voltage may have a quadrangular shape. That is, the first-1 voltage may be a discontinuous alternating current voltage. Referring to FIG. 19, in the primary aligning (S3), the waveform of the first-1 voltage may have a trapezoidal shape.

Because, when the first-1 voltage has the voltage shown in FIGS. 18 and 19, the change in voltage per time is greater than when the first-1 voltage has the voltage shown in FIG. 14, the change in the shape of the solution 1752 may be greater.

The graphs representing the waveform of the first-1 voltage shown in FIGS. 14, 16, 18, and 19 are just one of examples, the waveform of the first-1 voltage may be various.

Referring to FIGS. 12, and 14-19, in the primary aligning (S3), the waveform of the first-1 voltage may change over time.

As an example, the first-1 voltage may be an alternating current voltage as shown in FIG. 14, and after a designated time has elapsed, it may be converted into a direct current voltage as shown in FIG. 16.

As a waveform applied to the first-1 voltage is various, turbulence may be formed in the display part disposed on the display panel DP. That is, in a plan view, the solution 1752 may flow in the second direction, and the light-emitting element 1751 floating on the solution 1752 may be evenly spread in the second direction.

According to one or more embodiments, visibility and quality of the display apparatus may improve.

Effects, aspects, and features of the present disclosure are not limited to the above-mentioned effects, aspects, and features, and other effects, aspects, and features not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

1 what is claimed is:

1. A method of manufacturing a display apparatus, the method comprising:
disposing, on a jig part, a display panel comprising a first electrode and a second electrode;
spraying, on the display panel, a plurality of light emitters, each of the plurality of light emitters comprising a light-emitting element and a solution;
primarily aligning the plurality of light emitters by applying a first-1 voltage to the first electrode and applying a first-2 voltage to the second electrode; and
secondarily aligning the plurality of light emitters by applying a second-1 voltage to the first electrode and applying a second-2 voltage to the second electrode.

2. The method of claim 1, wherein, compared to intervals between the light-emitting elements of the plurality of light emitters during the spraying of the plurality of light emitters, intervals between the light-emitting elements of the plurality of light emitters are more uniform on a plane during the primarily aligning of the plurality of light emitters.

3. The method of claim 1, wherein the first-1 voltage is a direct current voltage.

4. The method of claim 1, wherein the first-1 voltage is an alternating current voltage.

5. The method of claim 1, wherein a waveform of the first-1 voltage changes over time.

6. The method of claim 1, wherein the first-2 voltage is a ground voltage.

7. The method of claim 1, wherein the light-emitting element comprises:
a first semiconductor layer;
a second semiconductor layer; and
an active layer between the first semiconductor layer and the second semiconductor layer.

8. The method of claim 7, wherein, during the secondarily aligning of the plurality of light emitters, the first semiconductor layer is in contact with the second electrode, and the second semiconductor layer is in contact with the first electrode.

9. The method of claim 1, wherein the second-1 voltage is a direct current voltage.

10. The method of claim 1, wherein the second-2 voltage is a ground voltage.

11. A method of manufacturing a display apparatus, the method comprising:
disposing, on a jig part, a display panel comprising a first electrode and a second electrode;
spraying, on the display panel, a plurality of light emitters, each of the plurality of light emitters comprising a light-emitting element and solution;
respectively applying different voltages to the first electrode and the second electrode such that intervals between the light-emitting elements of the plurality of light emitters are more uniform on a plane compared to intervals between the light-emitting elements of the plurality of light emitters during the spraying of the plurality of light emitters; and
respectively applying different voltages to the first electrode and the second electrode such that the light-emitting element is in contact with each of the first electrode and the second electrode.

12. The method of claim 11, wherein, during the respectively applying of the different voltages to the first electrode and the second electrode such that the intervals between the light-emitting elements of the plurality of light emitters are uniform, a first-1 voltage is applied to the first electrode and a first-2 voltage is applied to the second electrode, and
during the respectively applying of the different voltages to the first electrode and the second electrode such that the light-emitting element is in contact with each of the first electrode and the second electrode, a second-1 voltage is applied to the first electrode and a second-2 voltage is applied to the second electrode.

13. The method of claim 12, wherein the first-1 voltage is a direct current voltage.

14. The method of claim 12, wherein the first-1 voltage is an alternating current voltage.

15. The method of claim 12, wherein a waveform of the first-1 voltage changes over time.

16. The method of claim 12, wherein the first-2 voltage is a ground voltage.

17. The method of claim 12, wherein the second-1 voltage is a direct current voltage.

18. The method of claim 12, wherein the second-2 voltage is a ground voltage.

19. The method of claim 11, wherein the light-emitting element comprises:
a first semiconductor layer;
a second semiconductor layer; and
an active layer between the first semiconductor layer and the second semiconductor layer.

20. The method of claim 19, wherein, during the secondarily aligning of the plurality of light emitters, the first semiconductor layer is in contact with the second electrode, and the second semiconductor layer is in contact with the first electrode.

21. A method of manufacturing an electronic device, the method comprising:
manufacturing a display apparatus, the manufacturing comprising:
disposing, on a jig part, a display panel comprising a first electrode and a second electrode;
spraying, on the display panel, a plurality of light emitters, each of the plurality of light emitters comprising a light-emitting element and a solution;
primarily aligning the plurality of light emitters by applying a first-1 voltage to the first electrode and applying a first-2 voltage to the second electrode; and
secondarily aligning the plurality of light emitters by applying a second-1 voltage to the first electrode and applying a second-2 voltage to the second electrode; and
communicatively coupling the display apparatus with a control circuit.
